(19) United States
(12) Patent Application Publication
(10) Pub. No.: US 2024/0204472 A1
(43) Pub. Date: Jun. 20, 2024

(54) OPTICAL DEVICE, LIGHT SOURCE DEVICE, AND OPTICAL FIBER LASER

(71) Applicant: FURUKAWA ELECTRIC CO., LTD., Tokyo (JP)

(72) Inventors: Tatsuya YOSHIZAKI, Tokyo (JP); Masaya NAKAZUMI, Tokyo (JP); Naoki HAYAMIZU, Tokyo (JP); Yuta ISHIGE, Tokyo (JP)

(73) Assignee: FURUKAWA ELECTRIC CO., LTD., Tokyo (JP)

(21) Appl. No.: 18/590,040

(22) Filed: Feb. 28, 2024

Related U.S. Application Data
(63) Continuation of application No. PCT/JP22/32873, filed on Aug. 31, 2022.

(30) Foreign Application Priority Data
Sep. 1, 2021 (JP) 2021-142725

(51) Int. Cl. H01S 3/094; H01S 3/04

(52) U.S. Cl. CPC H01S 3/094049; H01S 3/0407; H01S 3/094003

(57) ABSTRACT

An optical device includes: a base; a light emitting device arranged on the base and configured to output a laser beam; a plurality of optical parts arranged on the base and configured to transmit the laser beam output from the light emitting device to an optical fiber to couple with the optical fiber, the plurality of optical parts including a first optical part and a second optical part; and a shielding portion arranged on the base and configured to shield stray light reflected on the second optical part so as to avoid the stray light from being irradiated to the first optical part.

This application is a continuation of International Application No. PCT/JP2022/032873, filed on Aug. 31, 2022 which claims the benefit of priority of the prior Japanese Patent Application No. 2021-142725, filed on Sep. 1, 2021, the entire contents of which are incorporated herein by reference.

### BACKGROUND

The present disclosure relates to an optical device, a light source device, and an optical fiber laser.

In the related art, an optical device that is equipped with a processing unit processing stray light (leakage light), which is light deviating from a predetermined optical path, has been known (for example, International Publication Pamphlet No. WO2017/134911).

### SUMMARY

For optical devices such as the optical device disclosed in International Publication Pamphlet No. WO2017/134911, it is important to suppress negative effects caused by stray light.

There is a need for an optical device, a light source device and an optical fiber laser equipped with a novel and improved configuration that enables to suppress negative effects caused by stray light.

According to one aspect of the present disclosure, there is provided an optical device including: a base; a light emitting device arranged on the base and configured to output a laser beam; a plurality of optical parts arranged on the base and configured to transmit the laser beam output from the light emitting device to an optical fiber to couple with the optical fiber, the plurality of optical parts including a first optical part and a second optical part; and a shielding portion arranged on the base and configured to shield stray light reflected on the second optical part so as to avoid the stray light from being irradiated to the first optical part.

According to another aspect of the present disclosure, there is provided an optical device including: a base; a light emitting device arranged on the base and configured to output a laser beam; a plurality of optical parts arranged on the base and configured to transmit a laser beam output from the light emitting device to an optical fiber to couple with the optical fiber; and a reflecting portion positioned with an offset in an opposite direction to a traveling direction of the laser beam through a first optical part with respect to the first optical part included in the optical parts, the reflecting portion being configured to reflect stray light reflected on a second optical device included in the optical parts to a direction deviating from the first optical part.

According to still another aspect of the present disclosure, there is provided an optical device including: a plurality of optical parts configured to transmit a laser beam to an optical fiber to couple with the optical fiber; and a shielding portion configured to shield stray light reflected on a second optical part included in the optical parts so as to avoid the stray light from being irradiated on a first optical part included in the optical parts.

### BRIEF DESCRIPTION OF DRAWINGS

FIG. 1 is an exemplary and schematic plan view of an optical device according to a first embodiment;

FIG. 2 is an exemplary and schematic perspective view of a base included in the optical device according to the first embodiment;

FIG. 3 is an exemplary and schematic side view of a subunit included in the optical device according to the first embodiment;

FIG. 4 is an exemplary and schematic perspective view of a portion including a shielding portion of the optical device according to the first embodiment;

FIG. 5 is an exemplary and schematic cross-sectional view of a part of the portion illustrated in FIG. 4;

FIG. 6 is an explanatory diagram illustrating a condition in which reflected light of stray light from a reflecting portion does not hit a bonding material in the optical device according to the first embodiment;

FIG. 7 is an explanatory diagram illustrating a condition in which reflected light of stray light from a reflecting portion does not hit a bonding material in an optical device according to a second embodiment;

FIG. 8 is an explanatory diagram illustrating a condition in which reflected light of stray light from a reflecting portion does not hit a first optical part in an optical device according to a third embodiment;

FIG. 9 is an exemplary and schematic perspective view of a part of an optical device according to a fourth embodiment;

FIG. 10 is an exemplary configuration diagram of a light source device according to an embodiment;

FIG. 11 is an exemplary configuration diagram of an optical fiber laser according to an embodiment; and

FIG. 12 is an exemplary and schematic side view of a subunit according to a modification of the embodiment.

### DESCRIPTION OF EMBODIMENTS

Hereinafter, exemplary embodiments and modifications will be disclosed. Configurations of the embodiments and modifications described below and actions and results (effects) produced by the configurations are one example. The present disclosure may be implemented by configurations other than those disclosed in the embodiments and modifications described below. Moreover, according to the present disclosure, at least one of various effects obtained by the configurations (including derived effects) may be obtained.

The embodiments and modifications described below have similar configurations. Therefore, according to the configuration of the respective embodiments and modifications, similar actions and effects based on those similar configurations may be obtained. Furthermore, in the following, identical reference symbols are assigned to identical components, and duplicated explanation may be omitted in some cases.

In the present specification, ordinal numbers are assigned for convenience to distinguish components, parts, directions, and the like, and do not indicate priority or sequence.

Moreover, in the respective drawings, an X1 direction is indicated by an arrow X1, an X2 direction is indicated by an arrow X2, a Y direction is indicated by an arrow Y, and a Z direction is indicated by an arrow Z. The X1 direction, the Y direction, and the Z direction intersect one another, and are perpendicular to one another. Moreover, the X1 direction and the X2 direction are opposite directions to each other.

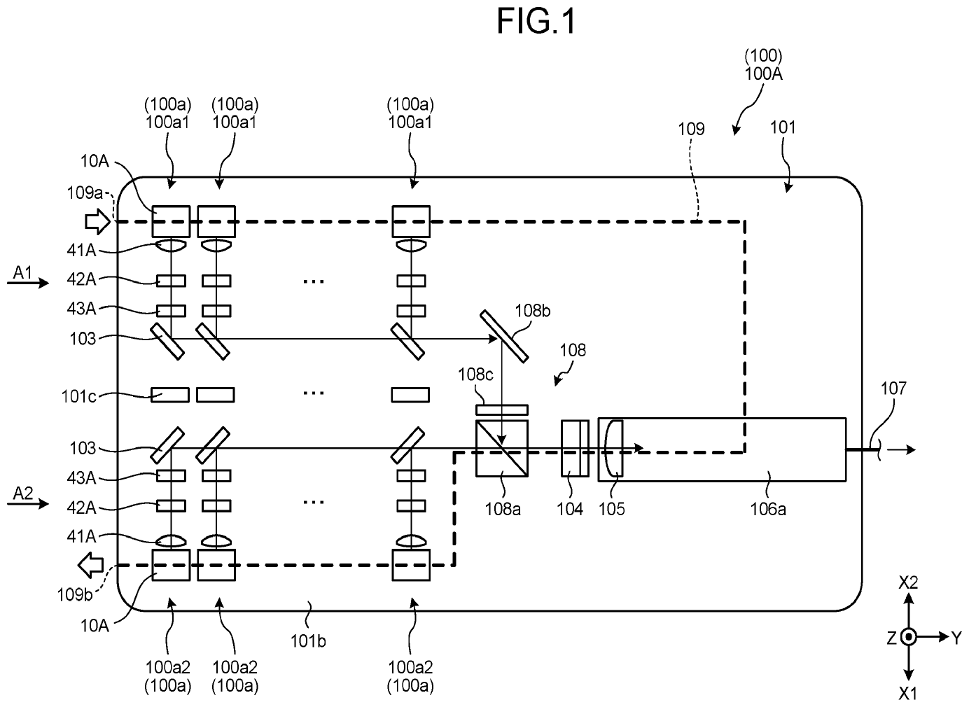

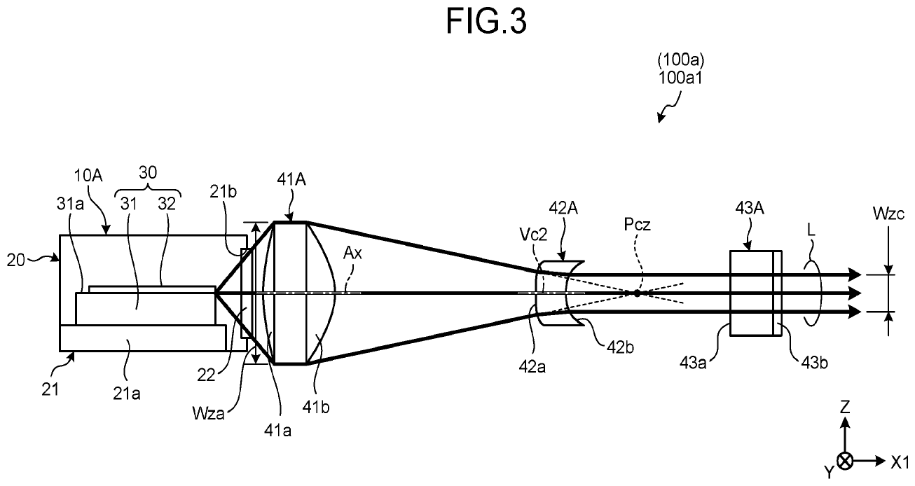

In FIGS. 1 and 3, an optical path of a laser beam L is indicated by a solid line arrow.

FIG. 1 is a schematic configuration diagram of an optical device 100A (100) according to a first embodiment, and is a plan view illustrating an internal portion of the optical device 100A viewed in an opposite direction to the Z direction.

As illustrated in FIG. 1, the optical device 100A includes a base 101, multiple subunits 100a, a light coupling unit 108, a light collecting lenses 104, 105, and an optical fiber 107. Laser beams output from a light emitting module 10A of the respective subunits 100a are transmitted to an end portion (not illustrated) of the optical fiber 107 through a mirror 103 of the respective subunits 100a, the light coupling unit 108, and the light collecting lenses 104, 105, and are optically combined with the optical fiber 107. The optical device 100A is also called light emitting device.

The base 101 is made from a material having high thermal conductivity, such as a copper-based material and an aluminum-based material. The base 101 may be constituted of a single part, or may be constituted of multiple parts. Moreover, the base 101 is covered with a cover (not illustrated). The subunits 100a, the mirrors 103, the light coupling unit 108, the light collecting lenses 104, 105, and the end portion of the optical fiber 107 are all arranged on the base 101, and are housed in a housing room (not illustrated) formed between the base 101 and the cover. The housing room is airtight.

The optical fiber 107 is an output optical fiber, and is fixed to the base 101 through a fiber supporting portion 106a supporting its end portion.

The fiber supporting portion 106a may be structured integrally with the base 101 as a part of the base 101, or the fiber supporting portion 106a may be structured as a separate part from the base 101, and attached to the base 101 through a fixing tool, such as a screw.

Each of the subunits 100a includes a light emitting module 10a that outputs a laser beam, multiple lenses 41A to 43A, and the mirror 103. A lens 42A collimates a laser beam along a fast axis, and a lens 42B collimates a laser beam along a slow axis. The lenses 41A to 43A and the mirror 103 are one example of an optical part.

Moreover, the optical device 100A includes two arrays A1, A2 in which the subunits 100a are aligned at predetermined intervals in the Y direction. In a subunit 100a1 (100a) of the array A1, the light emitting module 10A outputs a laser beam in the X1 direction, the lenses 41A to 43A transmit the laser beam from the light emitting module 10A in the X1 direction, and the mirror 103 reflects the laser beam traveling in the X1 direction to the Y direction. In the subunit 100a1 (100a) of the array A2, the light emitting module 10A outputs a laser beam in the X2 direction, the lenses 41A to 43A transmit the laser beam from the light emitting module 10A in the X2 direction, and the mirror 103 reflects the laser beam traveling in the X2 direction to the Y direction.

In the present embodiment, the subunit 100a1 of the array A1 and the subunit 100a2 of the array A2 are aligned in the X1 direction (X2 direction). Between the subunit 100a1 and the subunit 100a2, a shielding portion 101c that shields stray light (leakage light) is arranged. When the subunit 100a1 of the array A1 and the subunit 100a2 are thus aligned in the X1 direction, for example, there is an advantage that the size of the optical device 100A in the Y direction is reduced. However, not limited thereto, the subunit 100a1 of the array A1 and the subunit 100a2 may be arranged off from each other. For example, the respective subunits 100a2 may be arranged so as to be aligned in the X1 direction with respect to gaps between the two subunits 100a1 that are adjacent thereto in the Y direction.

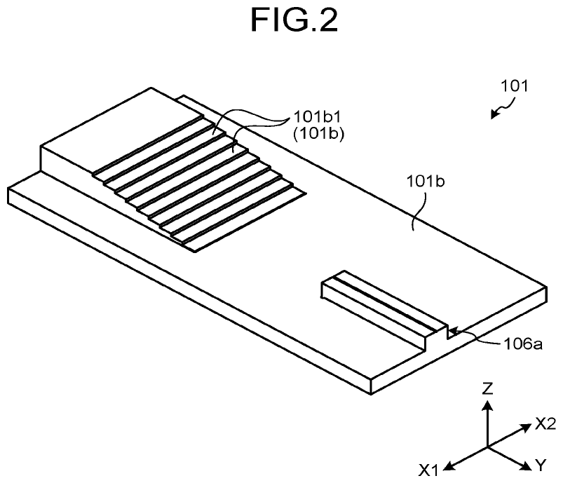

FIG. 2 is a perspective view of the base 101. As illustrated in FIG. 2, on a surface 101b of the base 101, multiple steps 101b1 that shift the position of the subunit 100a in a opposite direction to the Z direction as it approaches toward the Y direction are arranged. In each of the arrays A1, A2 in which the multiple subunits 100a are aligned at predetermined intervals (for example, at regular intervals) in the Y direction, the subunit 100a is arranged on each of the steps 101b1. By this arrangement, the position of the subunit 100a included in the array A1 in the Z direction is shifted to the opposite direction to the Z direction as it approaches toward the Y direction, and the position of the subunit 100a included in the array A2 in the Z direction is also shifted to the opposite direction of the Z direction as it approaches toward the Y direction. Such a configuration enables to input laser beams aligned in the Z direction parallel to each other and traveling in the Y direction to the light coupling unit 108 from the multiple mirrors 103 in the respective arrays A1, A2. The steps 101b1 may be configured to be shifted in a direction inclined to the Y direction or to the opposite direction to the Y direction with respect to the z direction, such that laser beams travel in a direction having a predetermined elevation angle with respect to the Y direction from the respective mirrors 103.

As illustrated in FIG. 1, laser beams from the respective mirrors 103 are input to the light coupling unit 108, and are combined in the light coupling unit 108.

The light coupling unit 108 includes a combiner 108a, a mirror 108b, and a ½ wavelength plate 108c. The combiner 108a, the mirror 108b, and the ½ wavelength plate 108c are one example of the optical part.

The mirror 108b sends a laser beam from the subunit 100a of the array A1 to the combiner 108a through the ½ wavelength plate 108c. The ½ wavelength plate 108c rotates the polarization plane of light from the array A1.

A laser beam from the subunit 100a of the array A2 is directly input to the combiner 108a.

The combiner 108a couples laser beams from the two arrays A1, A2. The combiner 108a may also be called polarization coupling device.

The laser beam from the combiner 108a is collected by the light collecting lenses 104, 105 to the end portion (not illustrated) of the optical fiber 107, and optically coupled with the optical fiber 107, to be transferred within the optical fiber 107. The light collecting lenses 104, 105 are one example of the optical part.

Furthermore, in the base 101, a cooling path 109 for cooling the subunit 100a (the light emitting module 10A), the fiber supporting portion 106a, the light collecting lenses 104, 105, the combiner 108a, and the like is arranged. In the cooling path 109, for example, a cooling medium, such as coolant, flows. The cooling path 109 passes, for example, near a mounting surface of the respective components on the base 101, for example, right below them or in proximity to them, and the inside of the cooling path 109 and the cooling medium (not illustrated) in the cooling path 109 are thermally connected to parts and components subject to cooling, namely, the subunit 100a (the light emitting module 10A), the fiber supporting portion 106a, the light collecting lenses 104, 105, the combiner 108a, and the like. Heat exchange is performed between the cooling medium and the part and the components through the base 101, and the parts are cooled. An inlet 109a and an outlet 109b of the cooling path 109 are arranged at an end portion in the opposite direction to the Y direction of the base 101 as an example, but may be arranged at other positions.

FIG. 3 is a side view illustrating a configuration of the subunit 100a1 (100a) of the array A1. In the subunit 100a2 of the array A2, an arrangement of the optical parts and the transmission direction of laser beams are opposite to those of the subunit 100al, but has similar configuration to the subunit 100a1.

The light emitting module 10A includes a chip on submount 30 and a case 20 in which the chip on submount 30 is housed. The light emitting module 10A is illustrated such that the interior of the case 20 is seen through in FIG. 3.

The case 20 is a box in a rectangular parallelepiped shape, and houses the chip on submount 30. The case 20 includes a wall member 21 and a window member 22. The wall member 21 is made from, for example, a metal material. Moreover, the case 20 has a base 21a. The base 21a has a plate shape intersecting the Z direction. The base 21a is, for example, a part (bottom wall) of the wall member 21. The base 21a is made from a metal material having high thermal conductivity, such as oxygen-free copper. Oxygen-free copper is one example of a copper-based material. The base 21a may be arranged separately from the wall member 21.

At an end portion of the wall member 21 in the X1 direction, an opening portion 21b is arranged. To the opening portion 21b, the window member 22 that lets the laser beam L pass through is attached. The window member 22 intersects and is perpendicular to the X1 direction. The laser beam L output from the chip on submount 30 in the X1 direction passes through the window member 22, and exits from the light emitting module 10A. The laser beam L is output from the light emitting module 10A in the X1 direction.

A boundary portion of multiple members (not illustrated) constituting the wall member 21 (the case 20), a boundary portion between the wall member 21 and the window member 22, and the like are sealed so that gas does not pass through. That is, the case 20 is airtightly sealed. The window member 22 is a part of the wall member 21 also.

The chip on submount 30 includes a submount 31 and a light emitting device 32. The chip on submount 30 may also be called semiconductor laser module.

The submount 31 has a plate shape, for example, intersecting and perpendicular to the Z direction. The submount 31 may be constituted of an insulating material having relatively high thermal conductivity, such as aluminum nitride, ceramic, and glass. On the submount 31, a metalization layer 31a is formed as an electrode to supply electric power to the light emitting device 32.

The submount 31 is mounted on the base 21a. The light emitting device 32 is mounted on a top surface of the submount 31. That is, the light emitting device 32 is mounted on the base 21a through the submount 31, and is mounted on the base 101 through the submount 31 and the case 20.

The light emitting device 32 is, for example, a semiconductor laser device having a fast axis (FA) and a slow axis (SA). The light emitting device 32 has a thin long shape extending in the X1 direction. The light emitting device 32 emits the laser beam L to the X1 direction from an emission opening (not illustrated) arranged at an end portion in the X1 direction. The chip on submount 30 is mounted such that the fast axis of the light emitting device 32 is along the Z direction, and the slow axis is along the Y direction. The Z direction is one example of a fast axis direction and the Y direction is one example of a slow axis direction.

The laser beam L output from the light emitting device 32 is collimated at least in the Z direction and the Y direction, passing through the lens 41A, the lens 42A, and the lens 43A in this order. The lens 41A, the lens 42A, and the lens 43A are all arranged outside the case 20.

In the present embodiment, the lens 41A, the lens 42A, and the lens 43A are arranged in the X1 direction in this order. The laser beam L output from the light emitting device 32 passes through the lens 41A, the lens 42A, and the lens 43A in this order. Moreover, the optical axis of the laser beam L is linear while it is emitted from the light emitting device 32 and passes through the lens 41A, the lens 42A, and the lens 43A, and the fast axis direction of the laser beam L is along the Z direction, and the slow axis direction of the laser beam L is along the Y direction.

The lens 41A is slightly apart from the window member 22 in the X1 direction, or is in contact with the window member 22 in the X1 direction.

To the lens 41A, the laser beam L that has passed through the window member 22 enters. The lens 41A is a lens having an axially symmetric shape relative to a center axis Ax along the optical axis, and is configured as a rotator about the center axis Ax. The lens 41A is arranged such that the center axis Ax is along the X1 direction, and is coaxial with the optical axis of the laser beam L. An incident surface 41a and emission surface 41b of the lens 41A respectively have a rotation surface about the center axis Ax extending in the X1 direction. The emission surface 41b is a convex curved surface that is convex in the X1 direction. The emission surface 41b protrudes more than the incident surface 41a. The lens 41A is so-called convex lens.

A beam width of the laser beam L output from the lens 41A becomes narrower as it travels toward the X1 direction. The beam width is the width of the region in a beam profile of a laser beam in which the optical intensity is equal to or higher than a predetermined value. The predetermined value is, for example, 1/e2 of the peak optical intensity. Because the lens 41A converges the laser beam L in the Z direction, the Y direction, and a direction between the Z direction and the Y direction, an effect of reducing aberrations of the laser beam L is obtained.

The lens 42A has a plane symmetrical shape with respect to a virtual center plane Vc2 as a plane intersecting and perpendicular to the Z direction. An incident surface 42a and the emission surface 42b of the lens 42A have a bus line along the Y direction, and a cylindrical surface extending in the Y direction. The incident surface 42a is a convex surface that is convex in the opposite direction to the X1 direction. Moreover, the emission surface 42b is a concave surface that is concave in the X1 direction.

The lens 42A collimates the laser beam L in the Z direction, that is, along the fast axis, in a state in which a beam width Wzc in the Z direction is smaller than a beam width Wza in the Z direction on the incident surface 41a to the lens 41A. The lens 42A is a concave lens on a cross section perpendicular to the Y direction. The lens 42 may also be called collimate lens.

Moreover, the lens 42A is positioned closer to the lens 41A than a focus point Pcz of the laser beam L in the Z direction by the lens 41A. If the lens 42A is positioned farther from the lens 41A than the focus point Pcz in the Z direction, a focus point Pcz in the Z direction appears on an optical path of the laser beam L between the lens 41A and the lens 42A. In this case, there is a possibility of inconvenience being caused, such as accumulation of dust at the focus point Pcz in the Z direction at which the energy density is high. In that regard, in the present embodiment, because the lens 42A is positioned closer to the lens 41A than the focus point Pcz in the Z direction, the laser beam L is collimated by the lens 42A before it reaches the focus point Pcz. That is, according to the present embodiment, because the focus point Pcz in the Z direction does not appear on the optical path of the laser beam L, it is possible to avoid inconvenience caused by the focus point Pcz.

Although the focus point (not illustrated) in the Y direction of the laser beam L appears between the lens 41A and the lens 42A, the energy density is not so high at a focus point in the Y direction and, therefore, a problem such as accumulation of dust does not occur.

The beam width in the Y direction of the laser beam L that has been output from the light emitting device 32 and has passed through the lens 41A and the lens 42A broadens as it travels in the X1 direction. To the lens 43A, the laser beam L that has broadened in the Y direction passing through the lens 42A enters.

The lens 43A has a plane symmetrical shape with respect to a virtual center plane as a plane intersecting and perpendicular to the Y direction. A incident surface 43a and an emission surface 43b of the lens 43A have a bus line along the Z direction, and a cylindrical surface extending in the Z direction. The incident surface 43a is a flat surface perpendicular to the X1 direction. Moreover, the emission surface 43b is a convex surface that is convex in the X1 direction.

The lens 43A collimates the laser beam L in the Y direction, that is, along the slow axis. The lens 43A is a convex lens on the cross section perpendicular to the Z direction. The lens 43A may also be called collimate lens.

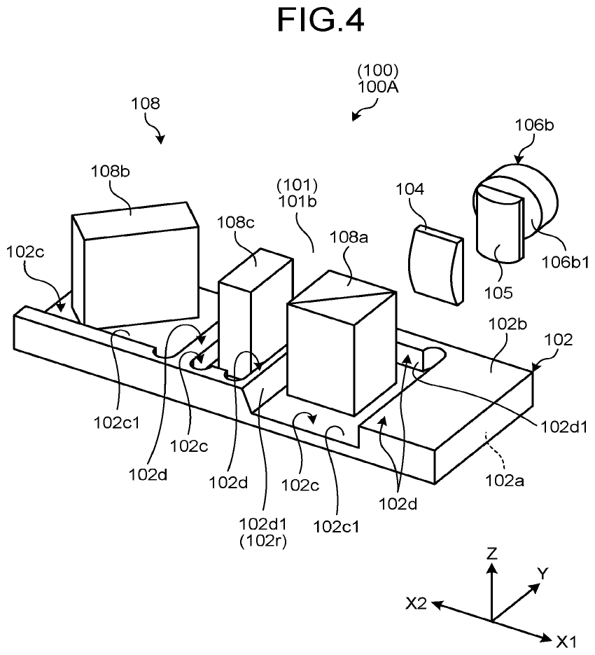

FIG. 4 is a perspective view including the light coupling unit 108 of the optical device 100A (100). As illustrated in FIG. 4, the optical device 100A includes an intermediate member 102. The intermediate member 102 is fixed to the base 101, and supports the combiner 108a, the mirror 108b, and the ½ wavelength plate 108c of the light coupling unit 108. The intermediate member 102 may also be called supporting member or intervening member.

The intermediate member 102 is made from a material, the thermal expansion coefficient of which takes a value between the thermal expansion coefficient of the base 101 that supports the intermediate member 102 and the thermal expansion coefficient of the optical parts, such as the combiner 108a, the mirror 108b, and the ½ wavelength plate 108c supported by the intermediate member 102. Examples of such a material of the intermediate member 102 include a ceramic material, such as alumina, AlN, and SiC, CuW such as 10Cu-90W, 20Cu-80W, and an alloy material such as cobalt.

The intermediate member 102 has a plate shape intersecting and perpendicular to the Z direction, and has a plate shape extending in the X1 direction, the X2 direction, and the Y direction. The intermediate member 102 includes a lower surface 102a and an upper surface 102b. The lower surface 102a and the upper surface 102b respectively intersect the Z direction and are perpendicular thereto, have a flat plane shape, and are parallel to each other.

The lower surface 102a is bonded to the surface 101b of the base 101, for example, by soldering, welding, bonding, or the like.

Moreover, at the upper surface 102b, multiple concave portions 102c that open toward the Z direction are arranged. The concave portion 102c is arranged corresponding to the combiner 108a, the mirror 108b, and the ½ wavelength plate 108c, respectively, and houses the combiner 108a, the mirror 108b, and the ½ wavelength plate 108c, respectively. That is, in the intermediate member 102, three concave portions 102c are arranged. The concave portion 102c may also be called housing unit.

The concave portion 102c has a bottom surface 102cl. The bottom surface 102cl faces the Z direction, and is intersecting and perpendicular to the Z direction, and has a flat plate shape. Moreover, the bottom surface 102cl is substantially parallel to the surface 101b of the base 101.

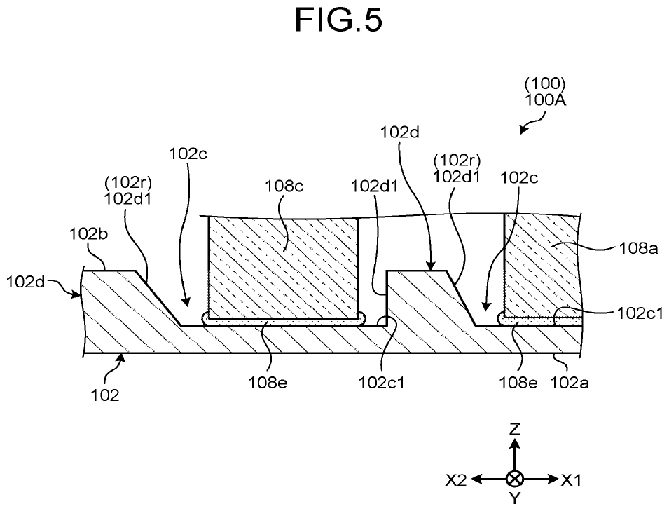

FIG. 5 is a cross-sectional view of a cross section of a part of FIG. 4 cut along the X1 direction, the X2 direction, and the Z direction. In FIG. 5, the intermediate member 102, the combiner 108a, and the ½ wavelength plate 108c are included. As illustrated in FIG. 5, the combiner 108a and the ½ wavelength plate 108c are bonded to the bottom surface 102c1 through a bonding material 108e. The bonding material 108e is arranged between the combiner 108a or the ½ wavelength plate 108c and the bottom surface 102cl. The bonding material 108e includes an organic material, such as epoxy resin and acrylic resin. The bonding material 108e may have an electromagnetic hardening property, a thermosetting property, or a humidity-curing property. Although not illustrated, the mirror 108b is also bonded to the bottom surface 102cl of the corresponding concave portion 102c through the bonding material 108e. The bottom surface 102cl is one example of a first surface.

If the bonding material 108e is an adhesive including an organic material, irradiation of stray light to the bonding material 108e may cause damage to the bonding material 108e. Stray light is originated from a laser beam deviated from a predetermined optical path as it is unintentionally reflected on the respective optical parts or passes through. As one example, stray light is a laser beam unintentionally reflected on an end surface 106b1 of an end cap 106b as illustrated in FIG. 4. The end cap 106b is optically coupled by fusion splicing or the like at an input end of the optical fiber 107, and has a function of suppressing damage to the input end by setting the energy density low at an input end of the laser beam compared to a case in which the laser beam is input to the optical fiber 107. With the end cap 106b, a laser beam that has passed through the mirror 108b, the ½ wavelength plate 108c, and the combiner 108a is coupled. That is, the end cap 106b is positioned ahead of the mirror 108b, the ½ wavelength plate 108c, and the combiner 108a in the optical path of the laser beam. In such a configuration, the mirror 108b, the ½ wavelength plate 108c, and the combiner 108a are one example of a first optical part, and the end cap 106b is one example of a second optical part.

To suppress negative effects of such stray light, the optical device 100A (100) includes a shielding portion 102d. The shielding portion 102d shields stray light that arrives in the opposite direction from the forward direction of the original optical path of the laser beam, such as reflected light unintentionally reflected on the end cap 106b, to prevent it from being irradiated to the bonding material 108e and an adjacent region or a vicinity of the bonding material 108e in the combiner 108a, the mirror 108b, and the ½ wavelength plate 108c.

The shielding portion 102d arranged with an offset in the Y direction with respect to the combiner 108a suppresses irradiation of stray light arriving in the opposite direction to the Y direction toward the combiner 108a or in a tilted direction to the opposite direction, to a part of the combiner 108a, and the bonding material 108e bonding the combiner 108a and the bottom surface 102cl.

The shielding portion 102d arranged with an offset in the X1 direction with respect to the mirror 108b and the ½ wavelength plate 108c suppresses irradiation of stray light that has been input in the opposite direction to the Y direction, or in a tilted direction to the opposite direction to the combiner 108a, and that has been reflected in the X2 direction or in a tilted direction to the X2 direction in the combiner 108a, to the mirror 108b and the ½ wavelength plate 108c, and the bonding material 108e bonding the mirror 108b or the ½ wavelength plate 108c with the bottom surface 102c1.

The shielding portion 102d is arranged at the intermediate member 102. The shielding portion 102d is constituted as a protrusion protruding from the bottom surface 102c1. The shielding portion 102d is one example of a first protrusion.

The shielding portion 102d is constituted as a side wall forming a side surface 102d1 of the concave portion 102c. The shielding portion 102d is one example of a first side wall.

Moreover, between the shielding portion 102d and the combiner 108a, the mirror 108b, and the ½ wavelength plate 108c, a gap is provided. This enables to prevent the shielding portion 102d from interfering with position adjustment in the X1 direction or the X2 direction of the combiner 108a, the mirror 108b, and the ½ wavelength plate 108c, respectively. Furthermore, with such a structure, when the combiner 108a, the mirror 108b, and the ½ wavelength plate 108c are attached through the bonding material 108e as the present embodiment, if the bonding material 108e is a bonding material having an electromagnetic hardening property, a thermosetting property, or a humidity-curing property, it is possible to easily subject the bonding material 108e to electromagnetic waves, heat, or steam from the gap.

Moreover, the shielding portion 102d may have an absorbing portion that absorbs stray light. The absorbing portion is, for example, a paint that converts the energy of a laser beam into thermal energy, such as black paint, applied on the side surface 102dl as an end surface of the shielding portion 102d in the traveling direction (the X1 direction) of the laser beam. Furthermore, the absorbing portion may be arranged on the upper surface 102b. With the absorbing portion, negative effects caused by reflected light on the shielding portion 102d may be suppressed.

Moreover, there is a possibility that stray light arriving from the forward direction in the traveling direction of the laser beam on the optical parts causes negative effects as it is reflected rearward of the optical part. Therefore, in the present embodiment, to suppress such negative effect caused by reflected light of stray light, the optical device 100A (100) includes a reflecting surface 102r that reflects stray light toward a predetermined direction. The reflecting surface 102r is one example of a reflecting portion.

As illustrated in FIG. 5, the reflecting surface 102r is positioned with an offset in the X2 direction, which is the opposite direction to the traveling direction of a laser beam, with respect to the combiner 108a, the ½ wavelength plate 108c, and the bonding material 108e, respectively, and reflects stray light arriving in the X2 direction, which is the opposite direction to the traveling direction of a laser beam, or in a direction inclined with respect to the X2 direction toward a predetermined direction. Thus, negative effects caused by reflected light of stray light are suppressed.

The reflecting surface 102r is arranged on the intermediate member 102. The reflecting surface 102r is constituted as the side surface 102d1 of the shielding portion 102d as the protrusion protruding from the bottom surface 102c1. The shielding portion 102d having the reflecting surface 102r is one example of the second protrusion.

The reflecting surface 102r is constituted as the side surface 102d1 of the concave portion 102c. The shielding portion 102d having the reflecting surface 102r is one example of the second side wall.

Moreover, between the shielding portion 102d having the reflecting surface 102r and the combiner 108a and the ½ wavelength plate 108c, a gap is provided. This enables to prevent the reflecting surface 102r (the shielding portion 102d) from interfering with position adjustment in the X1 direction or the X2 direction of the combiner 108a and the ½ wavelength plate 108c, respectively. Furthermore, with such a structure, when the combiner 108a and the ½ wavelength plate 108c are attached through the bonding material 108e as the present embodiment, if the bonding material 108e is a bonding material having an electromagnetic hardening property, a thermosetting property, or a humidity-curing property, it is possible to easily subject the bonding material 108e to electromagnetic waves, heat, or steam from the gap.

Furthermore, the reflecting surface 102r may have an absorbing portion that absorbs stray light. The absorbing portion may suppress negative effects caused by reflected light on the reflecting surface 102r.

Moreover, as illustrated in FIG. 5, the shielding portion 102d arranged between the ½ wavelength plate 108c and the combiner 108a aligned along the optical path of a laser beam with an interval may have the reflecting surface 102r with respect to the combiner 108a positioned in a frontward direction of the optical path, besides serving as a shielding portion with respect to the ½ wavelength plate 108c positioned in a rearward direction of the optical path. With such a configuration, compared to a configuration in which a shielding portion and a reflecting surface 102r are provided separately, for example, advantageous effects, such as achievement of more compact configuration and reduction in manufacturing effort and cost of the optical device 100A because of a simplified configuration, may be obtained. The shielding portion 102d arranged between the ½ wavelength plate 108c and the combiner 108a is one example of a wall portion.

The combiner 108a, the mirror 108b, and the ½ wavelength plate 108c may be attached directly to the base 101, instead of being attached indirectly to the base 101 through the intermediate member 102. Moreover, the shielding portion, the reflecting portion, the concave portion, the bottom surface and the side surface of the concave portion, the first protrusion, the second protrusion, the first side wall, the second side wall, and the wall portion may be arranged on the base 101.

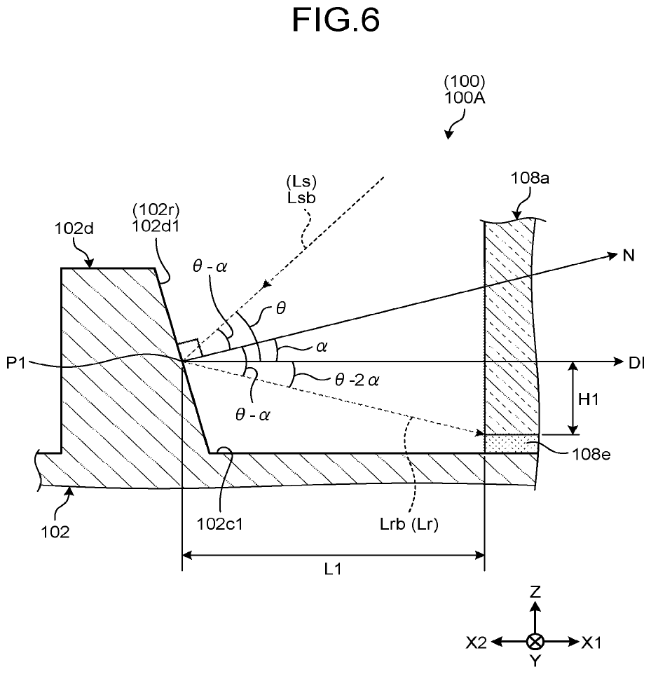

FIG. 6 is an explanatory diagram illustrating an example of a condition in which reflected light on the reflecting surface 102r does not hit the bonding material 108e in the optical device 100A (100). In FIG. 6, a case in which a tilted angle θ with respect to the X2 direction of stray light Ls is significantly larger than an actual situation is illustrated for easy understanding.

FIG. 6 assumes a case in which the bottom surface 102cl faces in the Z direction, and the stray light Ls travels in a direction tilted toward a direction approaching the bottom surface 102cl with respect to the X2 direction along a virtual plane along the Z direction and the X2 direction (that is, a direction along a sheet surface of FIG. 6). Furthermore, FIG. 6 illustrates a case in which a reflection point P1 on the reflecting surface 102r of an edge Lsb of the stray light Ls in the opposite direction to the Z direction is separated by a distance L1 in the X2 direction, and separated by a distance H1 in the Z direction from the bonding material 108e. The X2 direction is one example of a second direction.

Moreover, in the example in FIG. 6, a normal direction N of the reflecting surface 102r has a positive elevation angle α with respect to a D1 direction (X1 direction). In this case, an edge Lrb of reflected light Lr in the opposite direction to the Z direction to the edge Lsb of the stray light Ls is necessary to reach a position separated from the bonding material 108e in the Z direction. The entire reflected light Lr to the stray light Ls is then positioned off the edge Lrb in the Z direction and, therefore, the reflected light Lr is not to be irradiated to the bonding material 108e as a whole.

In FIG. 6, a state in which the edge Lrb of the reflected light Lr has just reached an end portion of the bonding material 108e in the Z direction is illustrated. In this case, as illustrated in FIG. 6, because an angle formed between the D1 direction, which is the opposite direction to the X2 direction, and the edge Lrb (the reflected light Lr) is θ−2α, H1=L1·tan (θ−2α) holds true. Therefore, when following equation (1) is satisfied,

$$H 1 < L 1 \cdot tan ( θ - 2 α ) \qquad ( 1 )$$

the edge Lrb of the reflected light Lr in the opposite direction to the Z direction reaches a position separated from the bonding material 108e in the Z direction, and the reflected light Lr is not to be irradiated to the bonding material 108e.

As explained above, in the present embodiment, the shielding portion 102d shields stray light that has been reflected on the second optical part, such as the end cap 106b, to avoid irradiation thereof to the first optical part, such as the combiner 108a, the mirror 108b, and the ½ wavelength plate 108c, and the bonding material 108e.

According to such a configuration, it is possible to suppress interference between stray light reflected on the second optical part and a laser beam transmitted by the first optical part, and to suppress occurrence of unfavorable events, such as damaging the bonding material 108e by the stray light.

Moreover, in the present embodiment, the reflecting surface 102r (reflecting portion) reflects stray light that has reflected on the second optical part to a predetermined direction.

According to such a configuration, it is possible to suppress interference between stray light reflected on the second optical part and a laser beam transmitted by the first optical part, and to suppress occurrence of unfavorable events, such as damaging the bonding material 108e by the stray light.

Moreover, the effects described above are particularly effective when an output of a laser beam is relatively high, when a wavelength of a laser beam is relatively short, when a usage period of a device is relatively long, and the like.

Furthermore, as the present embodiment, the shielding portion 102d and the reflecting surface 102r (reflecting portion) may be arranged in the intermediate member 102 fixed to the base 101.

According to such a configuration, for example, compare to a case in which the shielding portion 102d and the reflecting surface 102r are provided directly on the base 101, the shielding portion 102d and the reflecting surface 102r may be arranged more easily or more accurately, and this may enable to reduce manufacturing effort and cost of the optical device 100A.

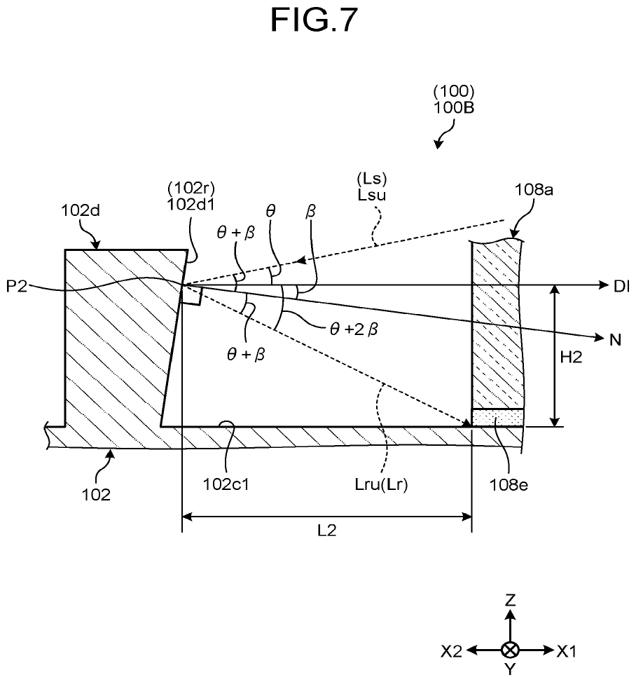

FIG. 7 is an explanatory diagram illustrating an example of a condition in which reflected light on the reflecting surface 102r does not hit the bonding material 108e in an optical device 100B (100) according to a second embodiment.

FIG. 7 assumes a case in which the bottom surface 102cl faces in the Z direction, and the stray light Ls travels in a direction tilted toward a direction approaching the bottom surface 102cl with respect to the X2 direction along a virtual plane along the Z direction and the X2 direction (that is, a direction along a sheet surface of FIG. 7). Furthermore, FIG. 7 illustrates a case in which a reflection point P2 on the reflecting surface 102r of an edge Lsu of the stray light Ls in the Z direction is separated by a distance L2 in the X2 direction, and separated by a distance H2 in the Z direction from the bonding material 108e.

Moreover, in the example in FIG. 7, the normal direction N of the reflecting surface 102r has a positive depression angle β with respect to the D1 direction (the X1 direction). In this case, an edge Lru of reflected light Lr in the Z direction to the edge Lsu of the stray light Ls is necessary to reach a position separated from the bonding material 108e in the opposite direction to the Z direction, or to a position separated from the bonding material 108e on the bottom surface 102cl in the X2 direction. The entire reflected light Lr to the stray light Ls is then positioned with an offset in the opposite direction to the Z direction with respect to the edge Lru and, therefore, the reflected light Lr is not to be irradiated to the bonding material 108e as a whole.

In FIG. 7, a state in which the edge Lru of the reflected light Lr has just reached an end portion of the bonding material 108e in the Z direction is illustrated. In this case, as illustrated in FIG. 7, because an angle formed between the D1 direction, which is the opposite direction to the X2 direction, and the edge Lru (the reflected light Lr) is θ+2β, H2=L2·tan (θ+2β) holds true. Therefore, when following equation (2) is satisfied,

$$H 2 > L 2 \cdot tan ( θ + 2 β ) \qquad ( 2 )$$

the edge Lru of the reflected light Lr in the Z direction reaches a position separated from the bonding material 108e in the opposite direction to the Z direction, in other words, a position separated from the bonding material 108e in the X2 direction on the bottom surface 102cl, and the reflected light Lr is not to be irradiated to the bonding material 108e.

According to the present embodiment as described also, effects similar to those of the first embodiment described above may be obtained.

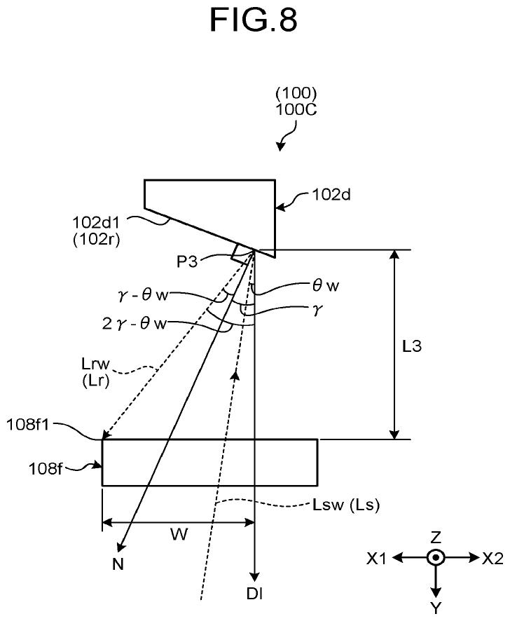

FIG. 8 is an explanatory diagram illustrating an example of a condition in which reflected light from the reflecting surface 102r does not hit an optical part 108f as the first optical part in an optical device 100C (100) according to a third embodiment.

FIG. 8 illustrates a case in which the stray light Ls that has been reflected on the second optical part and that travels in a direction between the opposite direction to the D1 direction (the Y direction) in which an original laser beam, not the stray light Ls, travels and the X2 direction is reflected on the reflecting surface 102r in a direction between the Y direction and the X1 direction. Moreover, FIG. 8 illustrates a case in which an end portion 108f1 of the optical part 108f in the X1 direction is separated by a distance L3 in the Y direction and is separated by a distance W in the X1 direction, with respect to a reflection point P3 on the reflecting surface 102r of an edge Lsw of the stray light Ls I the X2 direction. Furthermore, the stray light Ls travels toward the reflecting surface 102r at an angle tilted by an angle θw with respect to the opposite direction to the Y direction. The Y direction is one example of a third direction, and the X2 direction is one example of a fourth direction. FIG. 8 is a plan view when it is viewed in the opposite direction to the Z direction.

Moreover, in the example in FIG. 8, the normal direction N of the reflecting surface 102r has a tilted angle γ with respect to the D1 direction (the Y direction). In this case, an edge Lrw of reflected light Lr in the X2 direction to the edge Lsw of the stray light Ls in the X2 direction is necessary to reach a position separated in the X1 direction with respect to the end portion 108f1 of the bonding material 108e in the X1 direction. The entire reflected light Lr to the stray light Ls is then positioned off the edge Lrw in the X1 direction and, therefore, the reflected light Lr is not to be irradiated to the optical part 108f as a whole.

In FIG. 8, a state in which the edge Lrw of the reflected light Lr has just reached the end portion 108f1 of the optical part 108f in the X1 direction is illustrated. In this case, as illustrated in FIG. 8, because an angle formed between the D1 direction, which is the Y direction, and the edge Lrw (the reflected light Lr) is 2γ−θw, H3=L3·tan (2γ−θw) holds true. Therefore, when following equation (3) is satisfied,

$$H 3 > L 3 \cdot tan ( 2 γ - θ w ) \qquad ( 3 )$$

the edge Lrw of the reflected light Lr in the X2 direction reaches a position separated from the end portion 108f1 of the optical part 108f in the X1 direction, and the reflected light Lr is not to be irradiated to the optical part 108f.

According to the present embodiment as described also, effects similar to those of the first embodiment or the second embodiment described above may be obtained.

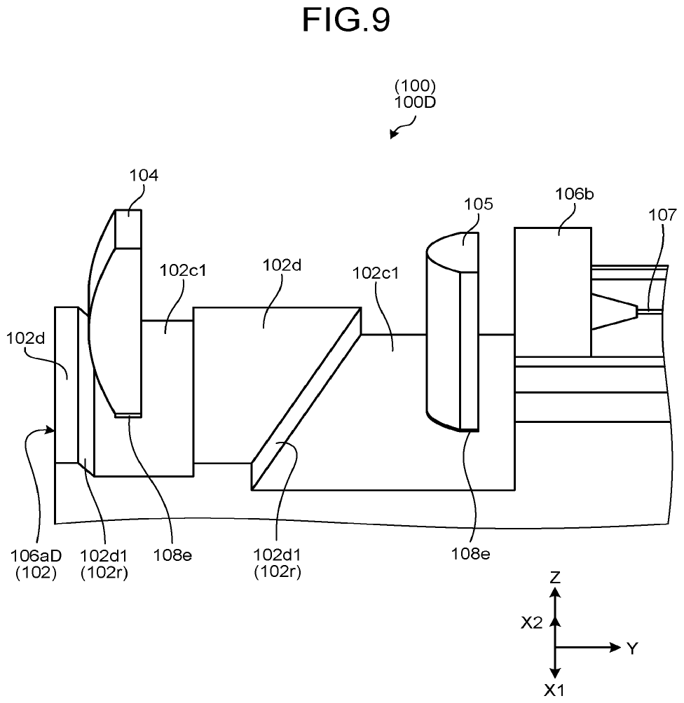

FIG. 9 is a perspective view of a part of an optical device 100D (100) according to a fourth embodiment. As illustrated in FIG. 9, the configuration including the shielding portion 102d and the reflecting surface 102r is applicable also to a portion in which the light collecting lenses 104, 105 are arranged. In the present embodiment, as an example, a fiber supporting portion 106aD is configured as a separate member from the base 101, and to the fiber supporting portion 106aD, the light collecting lens 104 is also bonded through the bonding material 108e, in addition to the light collecting lens 105. The fiber supporting portion 106aD functions as the intermediate member 102. The light collecting lenses 104, 105 are one example of the first optical part.

In the example in FIG. 9, the reflecting surface 102r arranged corresponding to the light collecting lens 104 reflects the stray light Ls to a direction between the Y direction and the Z direction or the opposite direction to the Z direction. On the other hand, the reflecting surface 102r arranged corresponding to the light collecting lens 105 reflects the stray light Ls to a direction between the Y direction and the X1 direction or the X2 direction. However, it is not limited to the configuration and arrangement as described above, and any configuration and arrangement may be applied as long as it is possible to avoid an adjacent region or a vicinity of the bonding material 108e in the light collecting lenses 104, 105 from being exposed to the stray light Ls by the shielding portion 102d, or to suppress the reflected light Lr of the stray light Ls from the reflecting surface 102r hitting on the bonding material 108e.

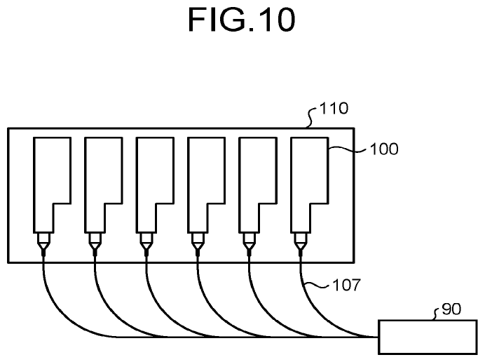

FIG. 10 is a configuration diagram of a light source device 110 according to a fifth embodiment in which the optical device 100 (light emitting device) of any one of the first to the second embodiments is mounted. The light source device 110 includes multiple units of the optical devices 100 as an excitation light source. Laser beams output from the optical devices 100 are transmitted to a combiner 90 as a light coupling unit through the optical fiber 107. An output end of the optical fiber 107 is respectively connected to multiple input ports of the multiple input single output combiner 90. The light source device 110 is not limited to one having multiple units of the optical devices 100, and is only required to have at least one unit of the optical device 100.

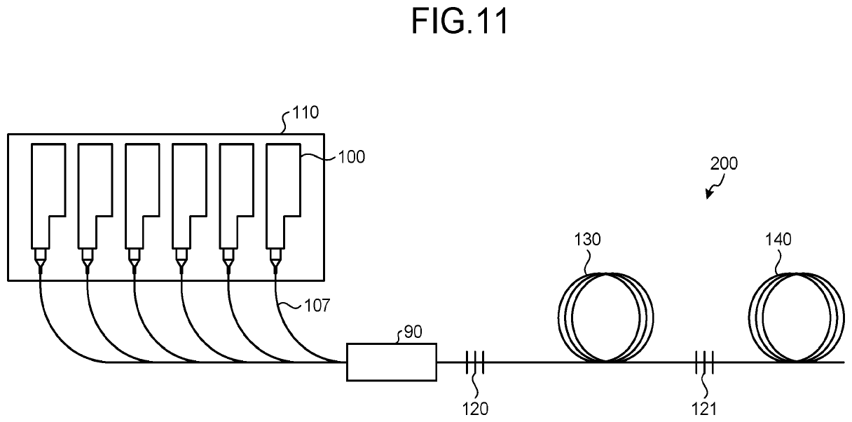

FIG. 11 is a configuration diagram of an optical fiber laser 200 in which the light source device 110 of FIG. 10 is mounted. The optical fiber 200 laser includes the light source device 110 illustrated in FIG. 10, the combiner 90, a rare-earth-dope optical fiber 130, and an output-side optical fiber 140. At an input end and an output end of the rare-earth-doped optical fiber 130, high-reflectivity fiber bragg gratings (FBG) 120, 121 are respectively arranged.

To the output end of the combiner 90, the input end of the rare-earth-doped optical fiber 130 is connected, and to the output end of the rare-earth-doped optical fiber 130, an input end of the output-side optical fiber 140 is connected. Note that as an input unit to input a laser beam output from the multiple optical devices 100 to the rare-earth-doped optical fiber 130, the combiner 90 may be replaced with other configurations. For example, it may be configured such that the optical fibers 107 of the output unit in the multiple optical devices 100 are arranged in a row, and a laser beam output from the multiple optical fibers 107 is input to the input end of the rare-earth-doped optical fiber 130 by using a input unit, such as an optical system including a lens. The rare-earth-doped optical fiber 130 is one example of an optical amplification fiber.

According to the light source device 110 of the fifth embodiment, or to the optical fiber laser 200 of the sixth embodiment, by providing the optical device 100 of the first to the fourth embodiments described above, effects similar to those of the first to the fourth embodiments are obtained.

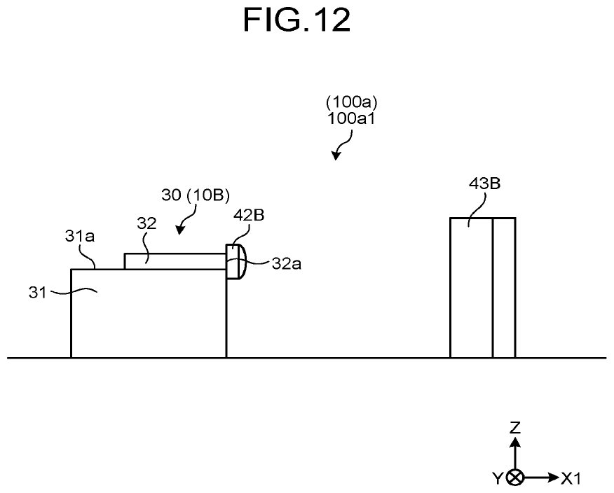

FIG. 12 is a side view illustrating another example (modification) of the subunit 100a1 (100a). The optical device according to a modification of the embodiment may be configured by replacing the subunit 100a of the optical device 100A in FIG. 1 with the subunit 100a in FIG. 12. As illustrated in FIG. 12, the subunit 100a1 of the present modification includes the chip on submount 30, the lens 42B, a lens 43B, and the mirror 103 (not illustrated in FIG. 12, refer to FIG. 1). The lens 42B collimates a laser beam along a fast axis, and the lens 43B collimates a laser beam along a slow axis. The lens 42B is integrated with the chip on submount 30 in a state facing an end surface 32a of the light emitting device 32. That is, in this example, a light emitting module 10B has the chip on submount 30 and the lens 42B integrally. The lenses 42B, 43B are one example of the optical part. In such a configuration including the subunit 100a1 (100a) also, effects similar to the embodiments described above may be obtained.

Although the embodiments and the modification have been exemplified above, the embodiments and the modification described above are one example, and it is not intended to limit the scope of the disclosure. The embodiments and the modification described above may be implemented in various other forms, and various omission, replacement, combination, and alteration may be applied within a range not departing the gist of the disclosure. Moreover, specifications including the respective components and shapes (structure, type, direction, model, size, length, width, thickness, height, number, arrangement, position, material, and the like) may be modified appropriately to be implemented.

For example, the optical part is not limited to those disclosed in the embodiments and the modification, and may be other optical devices that reflect, refract, or diffract light, such as a prism and diffractive optical device. The diffractive optical device is composed, for example, by combining multiple diffraction gratings with different periods into an integrated unit.

Moreover, configurations, arrangement, and combination of the subunit, the light emitting module, the respective optical parts, the protruding portion, the shielding portion, and the like are not limited to the embodiments and the modification described above. Furthermore, the traveling direction of stray light is also not limited to the directions described above.

According to the present disclosure, an optical device, a light source device, and an optical fiber laser equipped with a novel and improved configuration that enables to suppress, for example, negative effects caused by stray light may be obtained.

What is claimed is:

1. An optical device comprising:
a base;
a light emitting device arranged on the base and configured to output a laser beam;
a plurality of optical parts arranged on the base and configured to transmit the laser beam output from the light emitting device to an optical fiber to couple with the optical fiber, the plurality of optical parts including a first optical part and a second optical part; and
a shielding portion arranged on the base and configured to shield stray light reflected on the second optical part so as to avoid the stray light from being irradiated to the first optical part.

2. The optical device according to claim 1, wherein the second optical part is positioned in a frontward direction with respect to the first optical part on an optical path of the laser beam from the light emitting device to the optical fiber.

3. The optical device according to claim 1, wherein the shielding portion is positioned with an offset toward a traveling direction of the laser beam through the first optical part, with respect to the first optical part.

4. The optical device according to claim 1, wherein a gap exists between the shielding portion and the first optical part.

5. The optical device according to claim 1, wherein the shielding portion includes an absorbing portion configured to absorb the stray light.

6. The optical device according to claim 1, comprising
a reflecting portion positioned with an offset in an opposite direction to a traveling direction of the laser beam through the first optical part, with respect to the first optical part, the reflecting portion being configured to reflect the stray light in a predetermined direction.

7. The optical device according to claim 6, wherein a gap exists between the reflecting portion and the first optical part.

8. The optical device according to claim 6, wherein the reflecting portion includes an absorbing portion configured to absorb the stray light.

9. The optical device according to claim 6, comprising:
the first optical part includes two first optical units aligned with a gap therebetween on an optical path of the laser beam; and
a wall portion including, in an integrated manner,
the reflecting portion corresponding to one of the two first optical units that is positioned ahead in the optical path, and
the shielding portion corresponding to another one of the two first optical units that is positioned behind in the optical path.

10. The optical device according to claim 1, comprising:
a first surface arranged in any one of the base and an intermediate member fixed to the base; and
a bonding material that is present between the first surface and the first optical part, the bonding material being configured to bond the first surface and the first optical part, wherein
the shielding portion is configured to shield the stray light toward the bonding material.

11. The optical device according to claim 10, wherein the bonding material includes an organic material.

12. The optical device according to claim 10, wherein the shielding portion includes a first protrusion configured to protrude out from the first surface.

13. The optical device according to claim 10, wherein
the first surface includes a bottom surface of a concave portion arranged in any one of the base and the intermediate member, and
the shielding portion includes a first side wall forming a side surface of the concave portion.

14. The optical device according to claim 10, comprising
a reflecting portion positioned with an offset in a opposite direction to a traveling direction of the laser beam through the first optical part, with respect to the first optical part, the reflecting portion being configured to reflect the stray light to a direction deviating from the bonding material.

15. The optical device according to claim 14, wherein the reflecting portion includes a second protrusion configured to protrude out from the first surface.

16. The optical device according to claim 14, wherein
the first surface includes a bottom surface of a concave portion arranged in any one of the base and the intermediate member, and
the reflecting portion includes a second side wall forming a side wall of the concave portion.

17. The optical device according to claim 14, wherein
in a configuration in which the first surface is directed to a first direction, the stray light travels along a virtual plane along the first direction and a second direction perpendicular to the first direction, in a direction tilted toward the first surface with respect to the second direction, and a first reflection point on the reflecting portion of a first edge of the stray light in an opposite direction to the first direction is separated from the bonding material in the first direction and the second direction,
following equation 1 is satisfied, where a distance of the first reflection point from the bonding material in the second direction is L1, a distance of the first reflection point from the bonding material in the first direction is H1, a tilted angle of a traveling direction of the stray light with respect to the second direction is θ, and an elevation angle of a normal direction of the reflecting portion at the first reflection point with respect to a opposite direction to the second direction is α,
$$H 1 < L 1 \cdot tan ( θ - 2 α ) . \qquad ( 1 )$$

18. The optical device according to claim 14, wherein
in a configuration in which the first surface is directed to a first direction, the stray light travels along a virtual plane along the first direction and a second direction perpendicular to the first direction, in a direction tilted toward the first surface with respect to the second direction, and a second reflection point on the reflecting portion of a second edge of the stray light in the first direction is separated from the bonding material in the first direction and the second direction,
following equation 2 is satisfied, where a distance of the second reflection point from the bonding material in the second direction is L2, a distance of the second reflection point from the bonding material in the first direction is H2, a tilted angle of a traveling direction of the stray light with respect to the second direction is θ, and a depression angle of a normal direction of the reflecting portion at the second reflection point with respect to a opposite direction to the second direction is β,
$$H 2 > L 2 \cdot tan ( θ + 2 β ) . \qquad ( 2 )$$

19. The optical device according to claim 14, wherein
when a configuration in which the reflecting portion reflects the stray light traveling in a direction between an opposite direction to a third direction, which is a traveling direction of a laser beam in the first optical part, and a fourth direction perpendicular to the third direction, to a direction between the third direction and an opposite direction to the fourth direction, and the first optical part has an end point that is an end portion in the opposite direction to the fourth direction facing the reflecting portion, is viewed in a direction perpendicular to the third direction and the fourth direction,
following equation 3 is satisfied, where
a distance of a third reflection point of an edge of the stray light in the fourth direction on the reflecting portion from the end point is L3,
a distance from the third reflection point to the end point in an opposite direction to the fourth direction is W,
a tilted angle of the stray light toward the reflecting portion with respect to the opposite direction to the third direction is θw, and
a tilted direction of a normal direction of the reflecting portion at the third reflection point with respect to the third direction is γ
$$W > L 3 \cdot tan ( 2 γ - θ w ) . \qquad ( 3 )$$

20. The optical device according to claim 10, comprising the intermediate member, wherein
a thermal expansion coefficient of the intermediate member takes a value between a thermal expansion coefficient of the base and a thermal expansion coefficient of the bonding material.

21. An optical device comprising:
a base;
a light emitting device arranged on the base and configured to output a laser beam;
a plurality of optical parts arranged on the base and configured to transmit a laser beam output from the light emitting device to an optical fiber to couple with the optical fiber; and
a reflecting portion positioned with an offset in an opposite direction to a traveling direction of the laser beam through a first optical part with respect to the first optical part included in the optical parts, the reflecting portion being configured to reflect stray light reflected on a second optical device included in the optical parts to a direction deviating from the first optical part.

22. An optical device comprising:
a plurality of optical parts configured to transmit a laser beam to an optical fiber to couple with the optical fiber; and
a shielding portion configured to shield stray light reflected on a second optical part included in the optical parts so as to avoid the stray light from being irradiated on a first optical part included in the optical parts.

23. A light source device comprising
the optical device according to claim 1.

24. An optical fiber laser comprising:
the light source device according to claim 23; and
an optical amplification fiber configured to amplify the laser beam output from the light source device.
